(19) United States
(12) Patent Application Publication
(10) Pub. No.: US 2010/0314653 A1
(43) Pub. Date: Dec. 16, 2010

(54) SEMICONDUCTOR LIGHT-EMITTING ELEMENT

(76) Inventors: Kenji Orita, Osaka (JP); Shinji Yoshida, Osaka (JP)

Correspondence Address: MCDERMOTT WILL & EMERY LLP, 600 13TH STREET, NW, WASHINGTON, DC, 20005-3096, US

(21) Appl. No.: 12/866,436

(22) PCT Filed: Jun. 3, 2009
(86) PCT No.: PCT/JP2009/002506

§ 371 Date: Aug. 5, 2010

(30) Foreign Application Priority Data
Jun. 6, 2008 (JP) 2008-149514

(51) Int. Cl. H01L 33/10; H01L 33/30

(52) U.S. Cl. 257/98; 257/103; 257/E33.005; 257/E33.023

(57) ABSTRACT

A semiconductor light-emitting device includes a semiconductor multilayer (25) including a cavity structure having two facets facing each other, and a first protective film (23a) formed on at least one of the two facets and of metal nitride. The metal nitride contains aluminum and nitrogen as main components, and at least one of yttrium and lanthanum.

### TECHNICAL FIELD

The present invention relates to semiconductor light-emitting devices, and more particularly to semiconductor light-emitting devices having protective films on their facets.

### BACKGROUND ART

Group III-V compound semiconductors such as aluminium gallium arsenide (AlGaAs), aluminum gallium indium phosphide (AlGaInP), or aluminum indium gallium nitride (AlInGaN) are widely used for semiconductor light-emitting devices such as semiconductor laser diodes or light-emitting diodes having light-emitting wavelength ranging from an ultraviolet region to an infrared region.

FIG. 10 is a schematic view of a cross-sectional structure of a conventional semiconductor laser diode. As shown in FIG. 10, a first semiconductor layer 102 made of n-type group III-V compound semiconductor, a light-emitting layer 103 made of group III-V compound semiconductor, and a second semiconductor layer 104 made of p-type group III-V compound semiconductor are sequentially formed on an n-type semiconductor substrate 101 by epitaxial growth.

Furthermore, a p-side electrode 105 is formed on the second semiconductor layer 104. An n-side electrode 106 is formed on the surface of the n-type semiconductor substrate 101 opposite to the first embodiment layer 102.

The n-type semiconductor substrate 101, the first embodiment layer 102, the light-emitting layer 103, and the second semiconductor layer 104 are provided with two facets which are cleaved to face each other and function as cavity mirrors oscillating laser light. A front facet protective film 107, which is made of metal oxide such as silicon dioxide (SiO₂) or aluminum oxide (Al₂O₃), is formed on the front facet (a light-emitting facet) of the two facets. A rear facet protective film 108, which is a multilayer of metal oxide such as silicon dioxide (SiO₂) and zirconium dioxide (ZrO₂), is formed on the rear facet (a reflective facet) of the two facets. These protective films 107 and 108 are provided to control the reflectivity on the facets of the cavity, and to mitigate degradation of the semiconductor light-emitting device (see, e.g., Patent Document 1).

### Citation List

### Patent Document

PATENT DOCUMENT 1: Japanese Patent Publication No. H10-107362

PATENT DOCUMENT 2: Japanese Patent Publication No. 2000-49410

PATENT DOCUMENT 3: Japanese Patent Publication No. 2002-100830

PATENT DOCUMENT 4: Japanese Patent Publication No. 2007-27260

PATENT DOCUMENT 5: Japanese Patent Publication No. 2007-201373

### Non-Patent Document

NON-PATENT DOCUMENT 1: Bohadan Mrozienwicz, Maciej Bugajski, Wlodzimierz Nakwaski, “Physics of Semiconductor Lasers,” pp 447-457, North-Holland (1991)

### SUMMARY OF THE INVENTION

### Technical Problem

However, a conventional semiconductor laser diode having metal oxide such as SiO₂ or Al₂O₃ used for a facet protective film of a cavity, has the following problems in reliability.

When the metal oxide is formed on a facet of a semiconductor as the facet protective film, the facet of the semiconductor is oxidized by oxygen (O) used for forming the metal oxide film, thereby reducing the reliability of the semiconductor light-emitting device. A crystal defect such as vacancy is formed in the oxidized facet of the semiconductor. The formed crystal defect functions as a non-radiative recombination center. Non-radiative recombination of injected carriers occurs in the crystal defect, and energy corresponding to bandgap energy is regionally released near the crystal defect. This causes large distortion of the combination near the crystal defect to form a new crystal defect. Since the formation of the new crystal defect is supported by lattice vibration of the whole crystal, the formation of the crystal defect is accelerated with a rise in the temperature of the semiconductor laser diode. This phenomenon is known as recombination-enhanced defect reaction (REDR) which causes slow deterioration of semiconductor light-emitting devices including not only a semiconductor laser diode but also a light-emitting diode (see, e.g., Non-Patent Document 1).

Patent Document 2 and Patent Document 3 describe using nitride for a facet protective film of a semiconductor laser diode, and particularly using crystalline aluminum nitride (AlN) as a preferable material. AlN has a high melting point and high heat conductivity. Thus, even if the temperature for the film formation is reduced to the room temperature by sputtering, a film transparent even in the ultraviolet region can be easily available.

As a technique for improving adhesiveness of AlN to a semiconductor facet, Patent Document 4 and Patent Document 5 describe methods of adding silicon (Si) or oxygen (O) to AlN.

Patent Document 5 describes reducing the thickness of an AlN film to reduce internal stress caused by AlN and oxygen transmission. Patent Document 5 further describes providing metal oxide such as Al₂O₃, which is amorphous and has a small parameter of internal diffusion of oxygen, as a second facet protective film on the AlN film formed to be thin.

Furthermore, in a conventional semiconductor laser diode as shown in Patent Document 1, crystal defects increases. This increase in the crystal defects increases reactive currents due to non-radiative recombination, thereby reducing the lifetime of carriers. As a result, the threshold current increases with duration of operation. Being caused by injection of carriers, the increase in the crystal defects occurs with an operation current lower than a current causing laser oscillation. The increase in the crystal defects is seen in both of the front and rear facets.

The increase in the crystal defects due to the non-radiative recombination of the carriers is caused not only by the injected carriers but also by photoexcited carriers generated by light absorption of an active layer. When the non-radiative recombination of the photoexcited carriers occurs in the crystal defects, the increase in crystal defects due to the REDR is accelerated as in the defects caused by the injected carriers. These photoexcited carriers occur in the front facet having high light density, and thus, the degradation of the front facet usually proceeds faster than that of the rear facet. When the degradation of the facets proceeds, the temperature near the facets rises due to the non-radiative recombination. This temperature rise reduces the bandgap energy of the active layer near the facets to increase the light absorption, thereby accelerating the REDR caused by the photoexcited carrier. When the semiconductor laser diode further continues to operate, and the temperature near the facets exceeds a critical temperature, positive feedback, in which a decrease in the bandgap energy due to the light absorption causes another light absorption, occurs in a relatively short time. Eventually, the temperature near the facets of the active layer exceeds the melting point of the semiconductor to damage the smoothness of the semiconductor facets, thereby stopping the laser oscillation. This sudden breakdown is widely known as catastrophic optical mirror damage (COMD).

The present inventors found that, in a nitride compound semiconductor laser diode, the COMD, or degradation of facets as its precursory phenomenon is caused differently from that in a conventional group III-V compound semiconductor laser diode. Specifically, crystal defects easily occurring during operation of the nitride compound semiconductor laser diode are nitrogen vacancy and interstitial nitrogen. The interstitial nitrogen is externally diffused into a facet protective film with relative ease. When e.g., zirconium dioxide (ZrO₂) not dissolving the externally diffused nitrogen is used for the facet protective film, the diffused nitrogen atoms are combined with each other at the interface of the semiconductor and the facet protective film to produce nitrogen (N₂) gas. This removes the facet protective film from a facet of the semiconductor. This changes the reflectivity of the semiconductor facet to cause fluctuation in the operating current.

On the other hand, when Al₂O₃ or the like easily dissolving the externally diffused nitrogen is used for the facet protective film, the facet protective film having been amorphous during the formation of the film crystallizes during the operation, since nitrogen has strong covalency. This crystallization is accelerated by light energy when the facet protective film absorbs laser light by oxygen vacancy. This light absorption occurs in a blue-violet laser diode having photon energy closer to the bandgap of the facet protective film. Thus, crystallization of the facet protective film is not observed in e.g., a conventional AlGaAs semiconductor laser diode. Since the crystallization of the facet protective film contracts the volume of the semiconductor laser diode, stress is applied to the semiconductor facet to accelerate the defect formation in the semiconductor facet.

Oxidation of the semiconductor facet, which causes such facet degradation of the semiconductor laser diode, cannot be avoided as long as metal oxide is used as a facet protective film. In particular, the oxidation of the semiconductor facet significantly occurs in a group III nitride compound semiconductor. This is because, when being oxidized, N being a group V element in AlInGaN is removed from the semiconductor in a gas state as NOₓ so that the oxidation proceeds to the inside of the semiconductor.

In the techniques described in Patent Document 2 and Patent Document 3, an increase in crystal defects in semiconductor facets cannot be prevented during operation as during the formation of the metal oxide film. Furthermore, if AlN has a large thickness, the adhesiveness between the semiconductor facet and the AlN film is unstable so that the AlN film is easily removed from the semiconductor facet.

In the techniques described in Patent Document 4 and Patent Document 5, since a crystal defect occurs in the AlN film when doping silicon (Si) or oxygen (O), the heat conductivity of the AlN film is reduced to increase the diffusion rate of N or O. Furthermore, N or O is diffused through the crystal defect although such diffusion is usually prevented by a strong bond between Al and N. External diffusion of N from a nitride semiconductor, which was reduced by the AlN film, occurs to bury the nitrogen vacancy in the AlN film. This is considered as an essential problem when using a crystalline AlN film as the facet protective film, since the phenomenon, in which oxygen transmits the facet protective film of AlN, occurs not only inside the crystal but also through a grain boundary as described above.

Furthermore, in the structure shown in Patent Document 5, an amorphous second facet protective film is crystallized by laser light during the operation to damage the reliability of a semiconductor laser diode. Moreover, an AlN film is oxidized during the formation of the second facet protective film, and a facet of the semiconductor is oxidized. This results in reduction in the reliability of the semiconductor laser diode.

In view of the above-described conventional problems, it is an objective of the present invention to reduce oxidation of a first facet protective film to improve the reliability of a semiconductor light-emitting device, even if a second facet protective film is formed on the first facet protective film.

### Solution to the Problem

In order to achieve the above objective, in the present invention, a semiconductor light-emitting device is configured to contain in addition to aluminum and nitrogen, at least one of yttrium and lanthanum in a composition of a protective film provided on a facet of the semiconductor light-emitting device.

Specifically, the semiconductor light-emitting device according to the present invention includes a semiconductor multilayer including a facet, and a first protective film formed on the facet and made of metal nitride. The metal nitride contains aluminum and nitrogen as main components, and at least one of yttrium and lanthanum.

According to the semiconductor light-emitting device of the present invention, ion radiuses of yttrium (Y) and lanthanum (La) are 0.09 nm and 0.1 nm, respectively, which are extremely larger than 0.04 nm of aluminum (Al). Thus, Y or La is segregated at the grain boundary during the formation of a metal nitride film, specifically, an aluminum nitride (AlN) film. This reduces the size of each crystal particle of AlN as compared to the case where Y or La is not contained. That is, since the volume of the grain boundary in the whole AlN is increased by containing Y or La, the internal stress is reduced by the grain boundary. This results in reduction in distortion applied to the semiconductor facet from the facet protective film to mitigate an increase in the crystal defects on the semiconductor facet due to the REDR. This improves the reliability of the semiconductor light-emitting device. Furthermore, since Y and La having ion valence of three as Al does, Al or N is not damaged by a difference in ion valence even if Y or La is contained in AlN. Therefore, the advantage of reducing the internal diffusion of oxygen into the first protective film, and transmittance of laser light are not damaged.

In the semiconductor light-emitting device of the present invention, the metal nitride preferably contains silicon.

Usually, silicon (Si) is not combined with aluminum (Al), but forms a eutectic with aluminum (Al). Y and La do not form silicide with Si. Due to these properties, Si contained in AlN is combined with Y or La to be segregated at the grain boundary and on the semiconductor facet. As a result, even when metal nitride forming the first protective film contains Si, reduction in the heat conductivity of metal nitride, and an increase in an internal diffusion coefficient of oxygen are mitigated. At the same time, the adhesiveness of the first protective film improves as compared to the case where AlN does not contain Si, since Si is segregated on the semiconductor facet.

In the semiconductor light-emitting device of the present invention, the metal nitride is preferably crystalline.

The semiconductor light-emitting device according to the present invention further includes a second protective film formed on the first protective film, containing aluminum and oxygen as main components, and made of metal oxide containing at least one of yttrium and lanthanum.

With this configuration, aluminum oxide (Al₂O₃) forming the second protective film contains yttrium (Y) or lanthanum (La) having a larger ion radius than Al. This reduces crystallization of the amorphous Al₂O₃ during the operation of the light-emitting device. One of the reasons is that the O coordination number of Al is reduced in Al₂O₃ by containing Y or La. Specifically, Y or La having a larger ion radius than Al extrudes Al to an atom binding site with a small coordination number. It is well known that a decrease in the coordination number tends to reduce the crystallization temperature. Since the ion valences of Al, Y, and La are three, the lattice sites can be easily exchanged. Specifically, in a crystal state, an Al atom is combined with an O atom with the coordination number of 4, and Y and La atoms are combined with an O atom with the coordination number of 12 or 8. In an amorphous state, Al may have the coordination number of 8, and Y and La may have the coordination number of 4. Although such an Al—O compound with a large coordination number usually increases distortion energy to make the amorphous state unstable, the crystallization temperature may rise, since Y and La needed for the crystallization are hardly diffused. During the crystallization, since Al and Y, or Al and La exchange their binding site with O, large deformation of the atom binding is required to diffuse Y or La having a larger ion radius. This increases activation energy for Y or La diffusion. Furthermore, the second protective film contains Y or La which can be easily combined with oxygen, thereby reducing the oxidation of the first protective film during the formation of the second protective film. As a result, a decrease in the heat conductivity of the second protective film can be mitigated to prevent a rise in the temperature of the semiconductor facets. Also, internal diffusion of oxygen from the first protective film into the semiconductor facets can be reduced.

In this case, the metal oxide preferably contains nitrogen.

With this feature, the crystallization of Al₂O₃ can be further reduced by containing nitrogen (N) having strong covalency in metal oxide. This is because, a change in atomic position during the crystallization changes an atom bond angle, and the change in the atom bond angle is prevented by a strong Al—N bond. Specifically, since electron density is distributed in a specific direction in covalent binding, the change in the bond angle increases the binding energy. Due to these advantages, growth of crystal defects in the semiconductor facets caused by the crystallization of Al₂O₃ can be prevented.

In this case, the metal oxide is preferably amorphous.

In the semiconductor light-emitting device of the present invention, the semiconductor multilayer is preferably made of group III nitride semiconductor.

### Advantages of the Invention

The semiconductor light-emitting device according to the present invention improves the reliability of a semiconductor light-emitting device having a protective film on a facet.

### BRIEF DESCRIPTION OF THE DRAWINGS

FIG. 1 illustrates a cross-sectional structure of a semiconductor light-emitting device according to a first embodiment of the present invention.

FIGS. 2(a) and 2(b) illustrate cross-sectional structures in a method of manufacturing the semiconductor light-emitting device according to the first embodiment of the present invention in order of steps.

FIG. 3 illustrates a cross-sectional structure in a step of the method of manufacturing the semiconductor light-emitting device according to the first embodiment of the present invention.

FIG. 4(a) is a graph illustrating the dependency of oxidation of YAlN according to the first embodiment of the present invention on the depth from its surface. FIG. 4(b) is a graph illustrating the dependency of oxidation of AlN according to the first embodiment of the present invention on the depth from its surface.

FIG. 5(a) is a schematic perspective view illustrating an analysis method of internal stress in YAlN or AlN according to the first embodiment of the present invention. FIG. 5(b) is a graph illustrating the analysis result of the internal stress in YAlN or AlN according to the first embodiment of the present invention.

FIG. 6(a) illustrates a measurement result of crystal orientation of YAlN according to the first embodiment of the present invention. FIG. 6(b) illustrates a measurement result of crystal orientation of AlN according to the first embodiment of the present invention. FIG. 6(c) is a graph illustrating a measurement result of lattice constants of YAlN and AlN according to the first embodiment of the present invention.

FIG. 7(a) is a graph illustrating the dependency of absorbancy of infrared light in YAlN and AlN according to the first embodiment of the present invention on wave numbers. FIG. 7(b) is a graph illustrating the dependency of an attenuation coefficient in YAlN and AlN according to the first embodiment of the present invention on wavelength.

FIG. 8(a) is a graph illustrating a measurement result of crystallinity of YAlO according to the first embodiment of the present invention before and after annealing. FIG. 8(b) is a graph illustrating a measurement result of crystallinity of YAlON according to the first embodiment of the present invention before and after annealing.

FIG. 9 illustrates a cross-sectional structure of a semiconductor light-emitting device according to the second embodiment of the present invention.

FIG. 10 illustrates a cross-sectional structure of a conventional semiconductor light-emitting device.

### DESCRIPTION OF EMBODIMENTS

### First Embodiment

A first embodiment of the present invention will be described hereinafter with reference to the drawing.

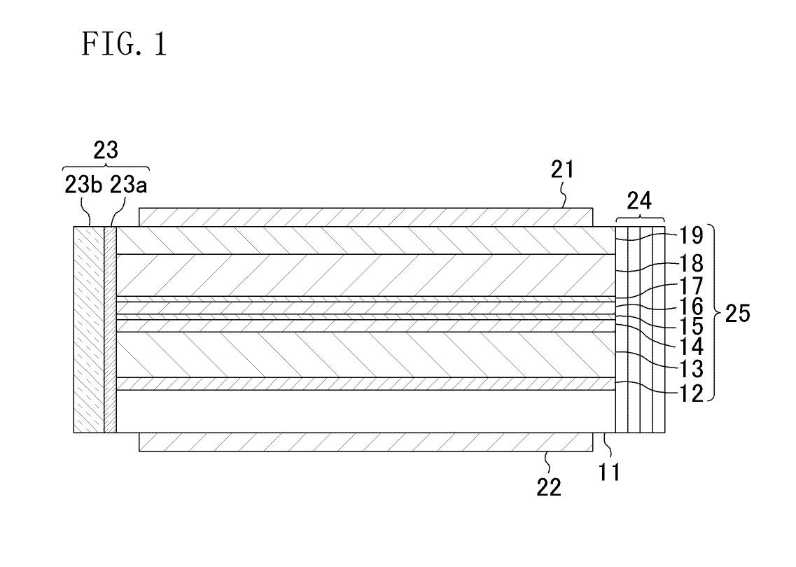

FIG. 1 illustrates a semiconductor light-emitting device according to the first embodiment of the present invention, and is a schematic view of a cross-sectional structure of a semiconductor laser diode made of group III nitride semiconductor.

As shown in FIG. 1, an n-type GaN layer 12 having a thickness of 1 μm and implanted with the concentration 1×10¹⁸ cm⁻³ of silicon (Si) as n-type dopant; an n-type cladding layer 13 having a thickness of 1.5 μm and made of n-type Al_{0.05}Ga_{0.95}N with a Si concentration of 5×10¹⁷ cm⁻³; an n-type optical guide layer 14 having a thickness of 0.1 μm and made of n-type GaN with a Si concentration of 5×10¹⁷ cm⁻³; a multiple quantum well active layer 15 including three cycles of a well layer having a thickness of 3 nm and made of undoped InGaN, and a barrier layer having a thickness of 7 nm and made of undoped In_{0.02}Ga_{0.98}N; a p-type optical guide layer 16 having a thickness of 0.1 μm and made of p-type GaN implanted with the concentration 1×10¹⁹ cm⁻³ of magnesium (Mg) as p-type dopant; a p-type electron blocking layer 17 having a thickness of 10 nm, made of p-type Al_{0.2}Ga_{0.8}N with a Mg concentration of 1×10¹⁹ cm⁻³; a superlattice cladding layer 18 formed by alternately stacking to the thickness of 0.5 μm, p-type Al_{0.1}Ga_{0.9}N and p-type GaN each of which has a Mg concentration of 1×10¹⁹ cm⁻³ and a thicknesses of 2 nm; and a p-type contact layer 19 having a thickness of 20 nm and made of p-type GaN with a Mg concentration of 1×10²⁰ cm⁻³ are sequentially formed by epitaxial growth, on a substrate 11 made of n-type gallium nitride (GaN). These group III nitride semiconductors form a semiconductor multilayer 25. In this embodiment, the In composition in a well layer of the multiple quantum well active layer 15 is determined so that an oscillation wavelength is 405 nm.

As will be described later, in the region from the lower portion of the p-type superlattice cladding layer 18 to the upper surface of the p-type contact layer 19, a stripe-shaped ridge waveguide laterally extending in the drawing is formed by removing the both sides of the region. A p-side electrode 21 made of palladium (Pd) is formed on the upper surface of the ridge waveguide. Furthermore, an n-side electrode 22 made of titanium (Ti) is formed on the surface of the substrate 11 opposite to the n-type GaN layer 12.

A front facet protective film (coating film) 23 including a first protective film 23a having a thickness of 5 nm and made of crystalline aluminum yttrium nitride (YAlN), and a second protective film 23b having a thickness of 120 nm and made of amorphous yttrium aluminum oxynitride (YAlON) is formed on a front facet (light-emitting facet) of the semiconductor laser diode. A rear facet protective film (coating film) 24 formed by alternately stacking silicon dioxide (SiO₂) and zirconium dioxide (ZrO₂) is formed on a rear facet (reflective facet). The reflectivity of the front facet protective film 23 is 18%. The reflectivity of the rear facet protective film 24 is 90%.

A manufacturing method of the semiconductor laser diode configured as above will be described hereinafter with reference to the drawings.

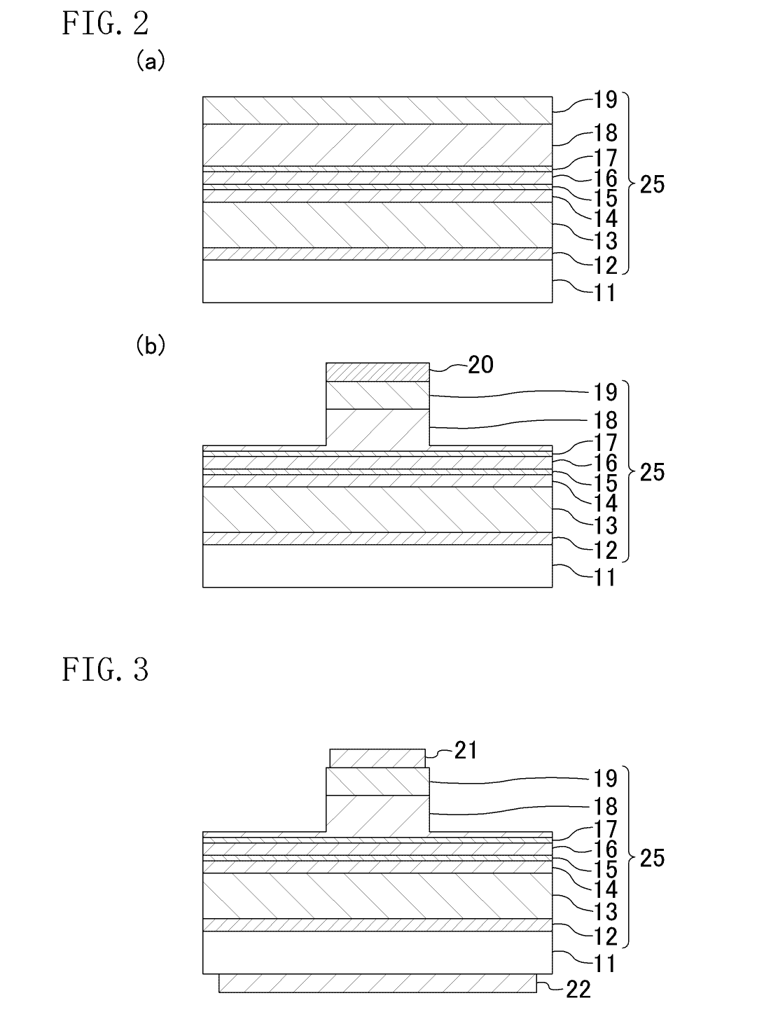

FIGS. 2(a), 2(b), and 3 are schematic views illustrating the cross-sectional structures of a manufacturing method of the semiconductor laser diode according to the first embodiment of the present invention in the order of steps.

First, as shown in FIG. 2(a), the n-type GaN layer 12, the n-type cladding layer 13 of n-type Al_{0.05}Ga_{0.95}N, the n-type optical guide layer 14 of n-type GaN, the multiple quantum well active layer 15 including three cycles of a well layer of undoped InGaN and a barrier layer of undoped In_{0.02}Ga_{0.98}N, the p-type optical guide layer 16 of p-type GaN, the p-type electron blocking layer 17 of p-type Al_{0.2}Ga_{0.8}N, the p-type superlattice cladding layer 18 formed by alternately stacking p-type Al_{0.1}Ga_{0.9}N and p-type GaN, and the p-type contact layer 19 made of p-type GaN are sequentially grown on the substrate 11 made of n-type GaN by e.g., metal organic chemical vapor deposition (MOCVD) to form the semiconductor multilayer 25. In this embodiment, for example, trimethylgallium (TMG) trimethylaluminum (TMA), and trimethylindium (TMI) are used as the group III source. For example, ammonia (NH₃) is used as the nitrogen source. Furthermore, silane (SiH₄) is used as the Si source which is n-type dopant, and cyclopentadienyl magnesium (Cp₂Mg) is used as the Mg source which is p-type dopant.

Next, after the crystal growth, a mask formation film made of silicon dioxide for formation of the ridge waveguide is deposited on the p-type contact layer 19. Then, as shown in FIG. 2(b), the mask formation film is pattered in a stripe shape, in which the crystal axis extends in the <1-100> direction (the front-back direction in the figure) with respect to the substrate 11 by lithography and etching so as to form a mask film 20. Thereafter, a ridge waveguide is formed in the p-type contact layer 19 and p-type superlattice cladding layer 18 by dry etching using the patterned mask film 20 and using chlorine gas as the main component. In the p-type superlattice cladding layer 18, the thickness of the ridge waveguide at the side portion (thickness of the remaining portion) is 0.1 μm. Furthermore, the width of the ridge waveguide is 2 μm at the lower portion, and 1.4 μm at the upper portion.

Then, as shown in FIG. 3, after removing the mask film 20, the p-side electrode 21 is formed on the stripe-shaped p-type contact layer 19. Next, after reducing the thickness of the film on the back surface of the substrate 11 so that the substrate 11 can be easily cleaved, the n-side electrode 22 is formed on the back surface of the substrate 11.

Thereafter, the substrate 11 and the semiconductor multilayer 25 are cleaved so that a cavity to be formed in the ridge waveguide has a length of 800 μm in order to form in the semiconductor multilayer 25, a facet mirror of which the cleavage is along the (1-100) plane of the plane orientation. For simplicity, the minus signs (“−”), which are associated with indexes in the crystal axis and the plane orientation, represent the inversions of the indexes following the minus signs.

After that, as shown in FIG. 1, in order to reduce degradation of the facets of a cavity in the semiconductor multilayer 25 and to control the reflectivity, the front facet protective film 23 including the first protective film 23a of YAlN and the second protective film 23b of YAlON is formed on the front facet of the semiconductor multilayer 25, and the rear facet protective film 24 formed by stacking a plurality of cycles of SiO₂/ZrO₂ is formed on the rear facet of the semiconductor multilayer 25.

In this embodiment, the basic function of the first protective film 23a is to reduce oxidization of the facets of the semiconductor multilayer 25 during formation of the second protective film 23b, and internal diffusion of oxygen during operation of the semiconductor laser diode. Thus, the thickness of the first protective film 23a is preferably large. On the other hand, an increase in the thickness of the first protective film 23a increases the internal stress, thereby reducing reliability of the laser diode. From this point of view, the thickness of the first protective film 23a is preferably small. In this embodiment, the thickness of the first protective film 23a is set to 5 nm in view of coatability of the semiconductor multilayer 25 to the facet.

The front facet protective film 23 according to the first embodiment can be formed by radio frequency (RF) sputtering, magnetron sputtering, electron cyclotron resonance (ECR) sputtering, or the like. The ECR sputtering is used in this embodiment. In the ECR sputtering, since the cleaved facet (the facet of a cavity) is not directly irradiated with sputter ions, the ion irradiation reduces the density of a crystal defect occurring in the facet of the cavity. Thus, the ECR sputtering is suitable for formation of a facet protective film in a semiconductor laser diode.

An Al metal target containing 5 atom % of yttrium (Y) is used as a target material for formation of the first protective film 23a made of YAlN and the second protective film 23b made of YAlON which are used for the front facet protective film 23. As the sputtering gas, nitrogen (N₂) gas and argon (Ar) gas are used for YAlN, and nitrogen (N₂) gas, oxygen (O₂) gas, and argon (Ar) gas are used for YAlON. Note that aluminum (Al) has different properties such as the atomic radius from yttrium (Y) and thus, the strength is reduced by adding more than 5 atom % of Y to Al metal. This causes difficulty in processing of the target material and the like. Therefore, in this embodiment, 5 atom % of Y is added. When using this target material, the Y concentration in the YAlN film is about 1 atom % in this embodiment. This may be because Al having a smaller atomic weight has a higher sputtering yield than Y having a larger atomic weight, when the sputtering gas collides with the target material.

Note that an Al₂O₃:La₂O₃ oxide sintered target may be used as the target material for formation of the YAlON film. However, as compared to the metal target which can obtain high purity by refining, the oxide sintered target has difficulty in improving the purity. When the oxide sintered target having low purity is used, impurities are mixed into YAlON, thereby causing light absorption in the second protective film 23b. Furthermore, when the oxide sintered target is used after forming the first protective film 23a of YAlN with a metal target, extra task time is needed for changing the target materials in manufacturing. From the foregoing, a target material is used for formation of the second protective film 23b of YAlON in the first embodiment. Note that a nitride target may be used instead of the metal target.

A plurality of semiconductor laser diodes, each of which has a conventional front facet protective film formed of a single layer of aluminum oxide (Al₂O₃), are formed as a first comparative example. A plurality of semiconductor laser diodes, each of which has a first protective film having a thickness of 5 nm and made of AlN, and a second protective film made of Al₂O₃, are formed as a second comparative example. In each of the comparative examples, the reflectivity of the front facet protective film is 18%.

The reliability of the semiconductor laser diodes according to the first embodiment formed as above will be described below. When the reliability test of continuous oscillation was conducted for 1000 hours at a temperature of 70° C. and with an optical output of 100 mW, the operating current of the semiconductor laser diodes according to the first comparative example has increased by 15% on average. Furthermore, in the first comparative example, laser oscillation has stopped in about 40% of the laser diodes having the same structures during the reliability testing because of the COMD occurred on the front facets. In the semiconductor laser diodes in the second comparative example, the operating current has increased by 10% on average. In about 20% of the laser diodes having the same structures during the reliability testing, the COMD has occurred on the front facets.

On the other hand, in semiconductor laser diodes each of which has the front facet protective film 23 including the first protective film 23a of YAlN and the second protective film 23b of YAlON as in the first embodiment, the increasing rate of the operating current was 5% on average. In all of the laser diodes having the same structures, the laser oscillation was available even after the reliability testing.

As such, the reliability of the semiconductor laser diodes according to the first embodiment has improved. The reasons are considered as follows. First, the facet of the semiconductor multilayer 25 during formation of the second protective film 23b made of YAlON which is metal oxynitride is prevented from being oxidized by the first protective film 23a underlying the second protective film 23b and made of YAlN which is metal nitride.

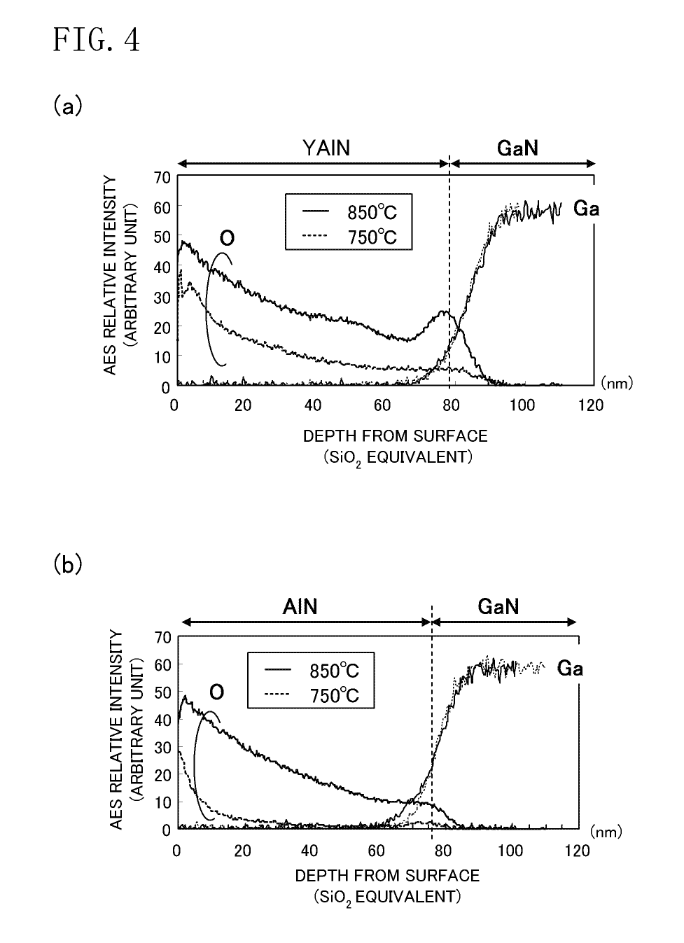

As such, the present inventors found that an YAlN film is more easily oxidized than an AlN film, and the oxidation of the underlying GaN is prevented when the AlN film or the YAlN film is formed on the (1-100) plane of the plane orientation of GaN and annealed in an oxygen atmosphere. The experimental results are shown in FIGS. 4(a) and 4(b). FIG. 4(a) illustrates the case of an YAlN film having a thickness of 30 nm, and FIG. 4(b) illustrates the case of an AlN film having a thickness of 30 nm. The both figures illustrate the results of composition analysis of oxygen (O) and gallium (Ga) in the depth (film formation) direction after annealing. In the experiments, the annealing was performed at temperatures of 750° C. and 850° C. for 30 minutes. An auger electron spectroscopy (AES) is used for the composition analysis. Even at such a high temperature as 800° C., at which GaN starts being oxidized and degraded, the YAlN film is merely sacrificially oxidized, while GaN starts being degraded and the degraded Ga is externally diffused into the AlN film. As such, the present inventors confirmed that the YAlN film reduces the oxidation and degradation of underlying GaN as compared to the AlN film.

Second, oxidation of the first protective film 23a during formation of the second protective film 23b is prevented by adding yttrium (Y) as the composition of the first protective film 23a and the second protective film 23b.

Third, as an advantage of adding Y to the first protective film 23a including AlN as a main component, the internal stress of the first protective film 23a is reduced as compared to the AlN film to reduce internal diffusion of oxygen into the first protective film 23a during operation of the laser diode as compared to the AlN film.

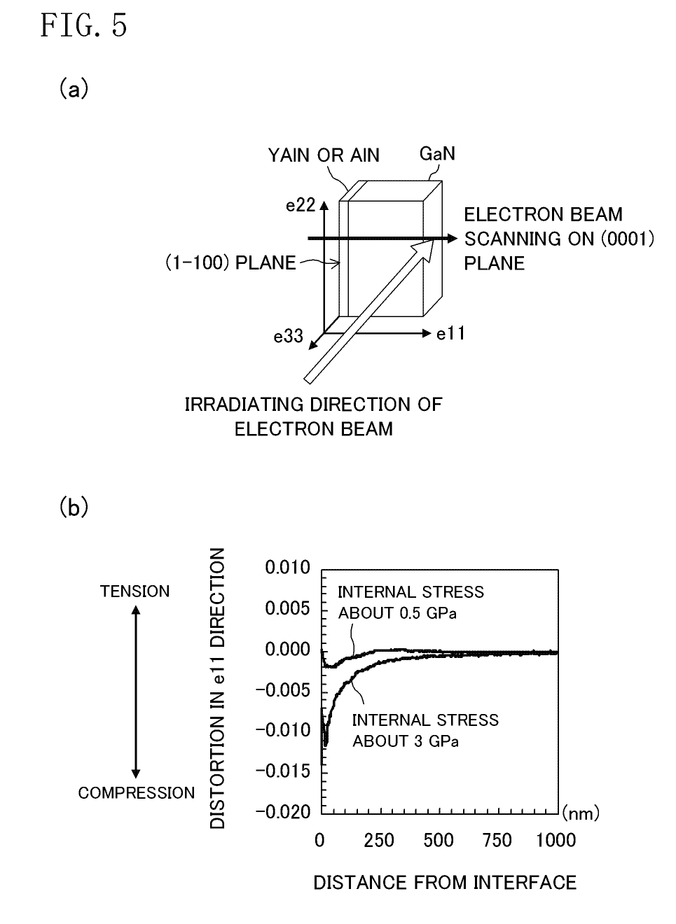

As such, the present inventors found that an YAlN film has smaller internal stress than an AlN film. FIGS. 5(a) and 5(b) illustrate analysis results of internal stress where an AlN film or YAlN film having a thickness of 30 nm is formed on the (1-100) plane of GaN. In order to analyze the internal stress of the AlN film and the YAlN film, the stress applied to the underlying GaN is analyzed. The stress applied to GaN from the AlN film or the YAlN film is represented by distortion of GaN calculated by an elastic constant of a bulk of GaN after comparing the lattice constant of GaN to a reference value as a bulk by electron backscatter diffraction (EBSD).

As shown in FIG. 5(a), the distortion of GaN is measured by electron beam scanning on the (0001) plane of GaN.

As shown in FIG. 5(b), compressive stress is applied to GaN from each of the AlN film and the YAlN film. However, the value of the internal stress is low in the YAlN film with about 0.5 GPa, which is one-sixth of that in the AlN film with about 3 GPa. The reduction in the stress applied to the underlying GaN mitigates progression of oxidation of GaN and degradation caused by the stress.

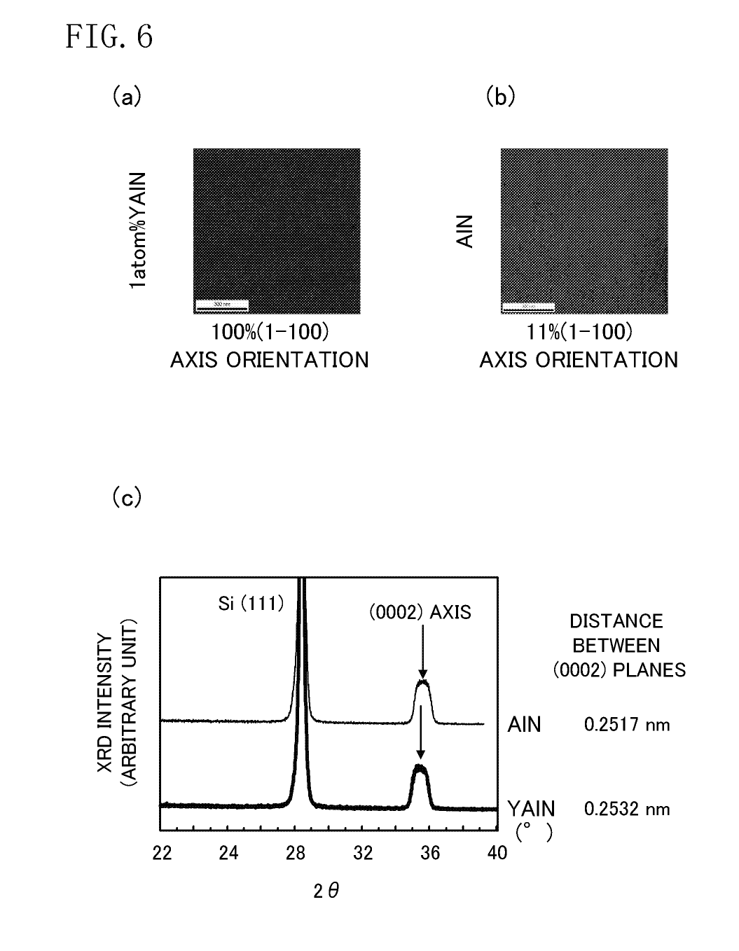

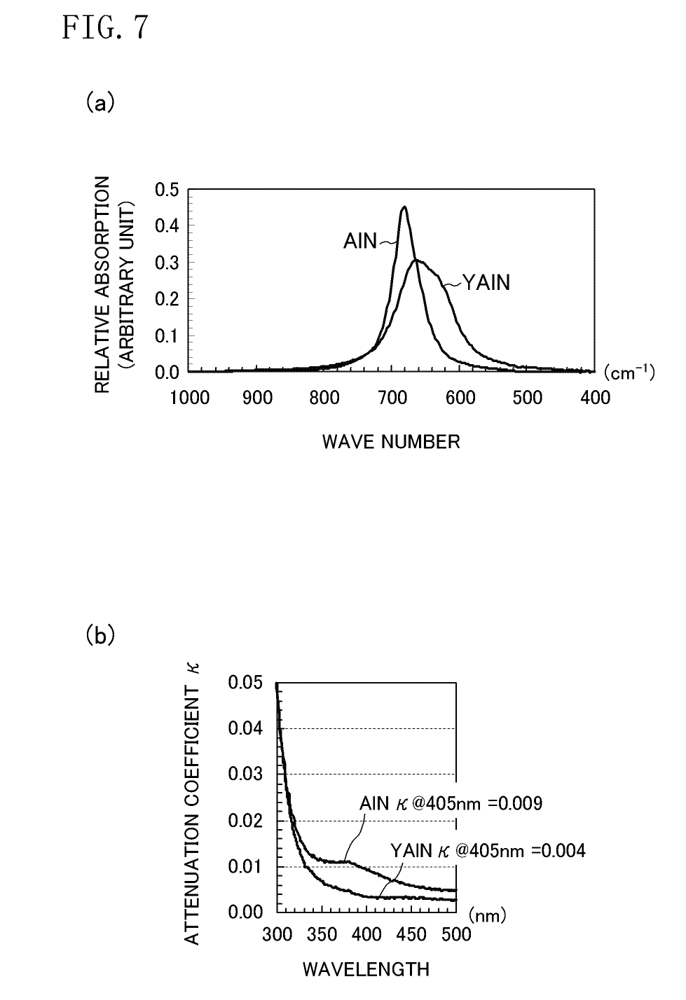

The present inventors found that an YAlN film has better crystal orientation and a smaller light absorption rate (attenuation coefficient) than an AlN film. FIGS. 6 and 7 illustrate the analysis results. FIGS. 6(a) and 6(b) illustrate measurement results of crystal orientation of the AlN film and YAlN film, each of which has a thickness of 30 nm and is formed on the (1-100) plane of GaN, measured from the (1-100) axis direction of the crystal axis by the EBSD. The crystal characteristics such as the crystal orientation depend on the conditions of the film formation. In the measurement, the flow rate of argon (Ar) is 20 ml/min (a standard state), and the flow rate of nitrogen (N₂) is 5 ml/min (a standard state) to obtain the same the conditions for film formation. The result shows that 100% of the crystals of the YAlN film shown in FIG. 6(a) are oriented along the (1-100) axis, and the crystal orientation in the plane is the same as that in the underlying GaN, i.e., the YAlN film is epitaxially formed. On the other hand, the crystals of the AlN film shown in FIG. 6(b) are, as is well known, primarily oriented along the (0001) axis, and the region in which the crystals are epitaxially oriented along the (1-100) axis with respect to the underling GaN accounts only for 11%.

There may be two reasons why the crystal orientation is changed by adding yttrium (Y) to aluminum nitride (AlN). First, Y has a large ion radius to increase the lattice constant of YAlN. Thus, Y is easily lattice-matched with GaN having a larger lattice constant than AlN to facilitate epitaxial film formation. Second, since Y has a large ion radius, Y is not easily introduced into the crystal during the formation of the YAlN film. As a result, Y is expelled to the growth front in high concentration, and thus, can function as a surfactant for changing the crystal growth mode.

Note that the present inventors confirmed by X-ray diffraction (XRD) analysis that YAlN has a larger lattice constant than AlN. The analysis result is shown in FIG. 6(c). The samples used for the analysis shown in FIG. 6(c) are made by forming an YAlN film and an AlN film, each of which has a thickness of 100 nm, on the (111) plane of the substrate of silicon (Si). As clear from FIG. 6(c), the YAlN film and the AlN film are oriented at the (0002) axis. When the distance between the (0002) planes is assumed by the diffraction angle, the distance is 0.2517 nm in the AlN film, and 0.2532 nm in the YAlN film. It can be seen that the distance in the YAlN film is larger than that in the AlN film by about 1%.

Also, in the YAlN film, the fact itself that yttrium (Y) exists in high concentration at the grain boundary cannot be confirmed by the composition analysis, since the size of the crystal grain is as small as tens of nm, and the average concentration of Y is as small as 1 atom %. However, nonuniform distribution indicating that yttrium (Y) exists in high concentration at the grain boundary was confirmed by Fourier transform infrared spectrometer (FT-IR). The analysis result is shown in FIG. 7(a). The samples used for the analysis are the same as those used in FIG. 6(c). As shown in FIG. 7(a), the AlN film has a single peak of infrared absorption at the position where the wave number is about 680 cm⁻¹. By contrast, an YAlN film has an absorption spectrum with two peaks, i.e., a main peak having larger strength at the position where the wave number is about 670 cm⁻¹, and a sub-peak having smaller strength at the position where the wave number is about 620 cm⁻¹. It is generally known that, in the lattice vibration in which a high-mass element such as yttrium (Y) is included, the wave number is small and the absorption peak strength is proportional to the volume of a substance. Thus, the main peak where the wave number is about 670 cm⁻¹ is considered to represent the absorption caused by vibration of YAlN which is introduced with Y in the crystal grain, contains low concentration of Y, and has large volume. The sub-peak where the wave number is about 620 cm⁻¹ is considered to represent the absorption caused by vibration of YAlN which is at the grain boundary, contains high concentration of Y, and has small volume.

As such, the lattice constant of YAlN is large, and Y functions as a surfactant during the crystal growth since Y exists in high concentration at the grain boundary. These two factors are considered to lead to epitaxial formation of the YAlN film on the underlying GaN.

Furthermore, the present inventors found that the YAlN film has a smaller light absorption rate (attenuation coefficient x) than the AlN film. FIG. 7(b) illustrates the dependency of the attenuation coefficients of the YAlN film and the AlN film on the wavelength. The samples used for the measurement shown in FIG. 7(b) are made by forming an YAlN film and an AlN film, each of which has a thickness of 300 nm, on a substrate made of heat-resistant hard glass such as borosilicate glass (e.g. Pyrex (registered trademark)). It is found from FIG. 7(b) that the YAlN film has a smaller attenuation coefficient than the AlN film. For example, the attenuation coefficient where the wavelength is 405 nm is 0.004 in the YAlN film, and 0.009 in the AlN film. These values include damages due to the light absorption of the heat-resistant hard glass and the light scattering due to the samples. Since the attenuation coefficient in the background is 0.004, the true attenuation coefficient is determined as a value near the measurement limit, i.e., 0, where the wavelength of the YAlN film is 405 nm.

There may be two reasons why the YAlN film has a smaller attenuation coefficient than the AlN film. First, as described above, the addition of yttrium (Y) improves the crystallinity to reduce the density of a crystal defect at the grain boundary, thereby reducing the light absorption by the crystal defect. Second, since Y is swept out to the grain boundary during the formation of YAlN, oxygen mixed into the inside of the crystal grain is combined with Y, which is easily combined with oxygen, in YAlN to form Y₂O₃ at the grain boundary during the formation of AlN. When Y is mixed into the inside of the crystal grain, a crystal defect occurs to absorb light in AlN. By contrast, when Y₂O₃ is formed at the grain boundary, the Y₂O₃ is transparent in a visible region. That is, light absorption caused by oxygen mixed into the film during the film formation can be reduced in the YAlN.

Fourth, as an advantage of adding Y and N to the second protective film 23b including Al₂O₃ as the main component, the crystallization of Al₂O₃ during the operation of the laser diode can be reduced. The composition of N added to the second protective film 23b is 30 atom %. The composition of N added to the second protective film 23b preferably ranges from 25 atom % to 40 atom %.

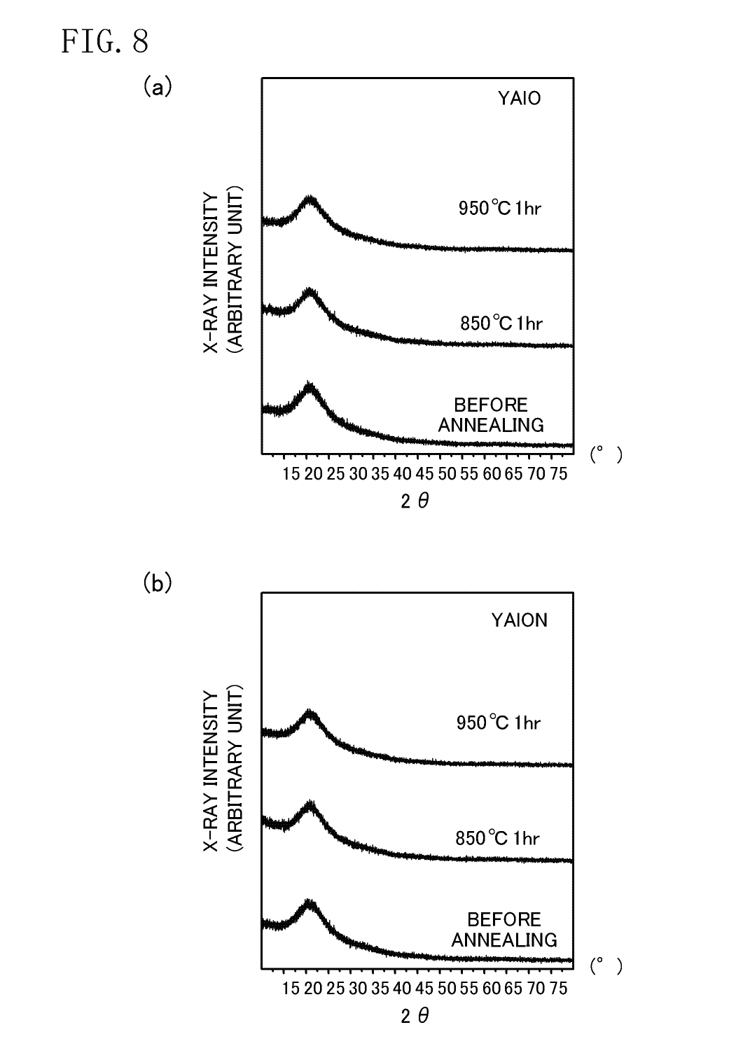

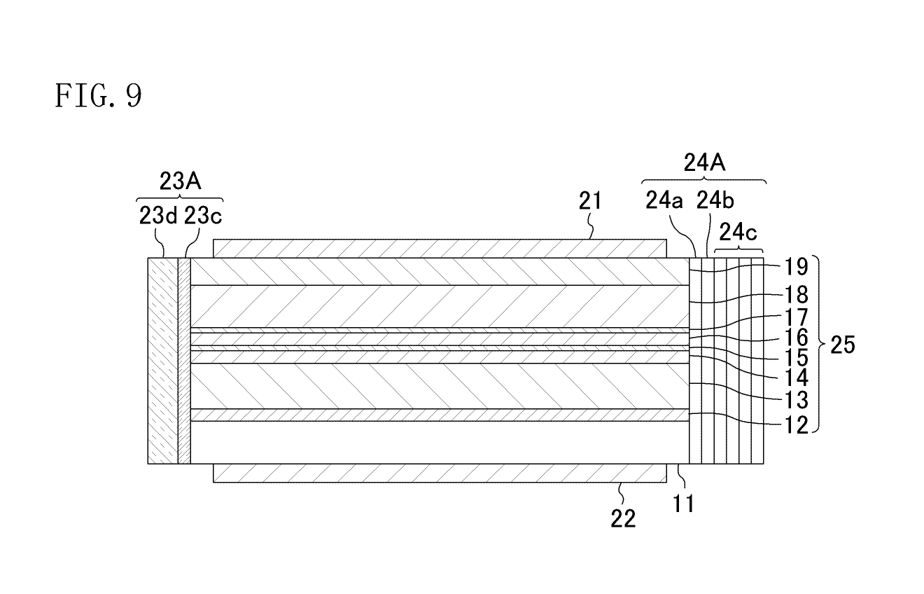

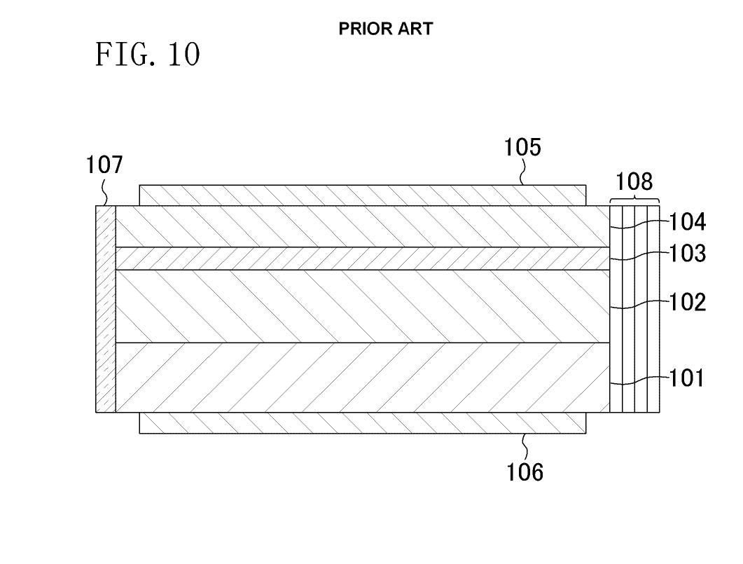

FIGS. 8(a) and 8(b) illustrate that crystallization during annealing is reduced in a YAlO film and a YAlON film. The samples used in this experiment are made by forming a YAlO film and a YAlON film, each of which has a thickness of 100 nm, on a substrate made of quartz glass. Each of the Y concentration in the YAlO film and the YAlON film is 1 atom %. In the YAlON film, the N concentration is 25%, and the O concentration is 31%. Note that the refractive indexes where the wavelength is 405 nm are 1.69 in YAlO and 1.83 in YAlON, which are increased by adding Y having larger atomic weight than 1.66 in Al₂O₃. On the other hand, the attenuation coefficient where the wavelength is 405 nm is at a background level and under the measurement limit, i.e., substantially 0, in both of YAlO and YAlON as in Al₂O₃. Annealing is performed in a nitrogen atmosphere at a temperature of 850° C. or 950° C. for 1 hour. In order to analyze crystallization, X-ray diffraction analysis is conducted before and after annealing. As shown in FIGS. 8(a) and 8(b), a broad signal seen at an angle near 20° in each X-ray diffraction spectrum is of the quartz glass of the substrate. Therefore, from each of the samples of YAlO and YAlON, a signal other than the signal of quartz glass is not observed before annealing, and thus, both of the samples are in amorphous states. Furthermore, after annealing, no X-ray diffraction signal is seen from the crystals in each of YAlO and YAlON. This shows that YAlO and YAlON are not crystallized in annealing at the temperature of 950° C. On the other hand, although it is now shown in the drawing, Al₂O₃ was in an amorphous state before annealing, but is crystallized when annealing at the temperature of 850° C. is performed. From this result, it can be confirmed that crystallization of Al₂O₃ can be reduced by adding Y or N.

### Second Embodiment

A second embodiment of the present invention will be described hereinafter with reference to the drawings.

FIG. 4 illustrates a semiconductor light-emitting device according to the second embodiment of the present invention, and is a schematic view of a cross-sectional structure of a semiconductor laser diode made of group III nitride semiconductor. In FIG. 4, the same reference characters as those shown in FIG. 1 are used to represent equivalent elements, and the explanation thereof will be omitted.

As shown in FIG. 4, a front facet protective film 23A according to the second embodiment includes a first protective film 23c formed on the front facet of the semiconductor multilayer 25, having a thickness of 30 nm, and made of crystalline lanthanum aluminum nitride (LaAlN); and a second protective film 23d formed on the first protective film 23c (on the surface of the first protective film 23c opposite to the semiconductor multilayer 25), having a thickness of 110 nm, and made of amorphous lanthanum aluminum oxynitride (LaAlON). The reflectivity of the front facet protective film 23A is 18% as in the first embodiment.

In the second embodiment, the rear facet protective film 24A of the semiconductor multilayer 25 includes a first protective film 24a having a thickness of 30 nm and made of crystalline lanthanum aluminum nitride (LaAlN); a second protective film 24b formed on the first protective film 24a (on the surface of the first protective film 24a opposite to the semiconductor multilayer 25), having a thickness of 30 nm, and made of amorphous lanthanum aluminum oxynitride (LaAlON); a third protective film 24c formed by stacking a plurality of cycles of SiO₂/ZrO₂. The reflectivity of the rear facet protective film 24A is 90% as in the first embodiment.

The first protective film 23c and the second protective film 23d forming the front facet protective film 23A as well as the first protective film 24a and the second protective film 24b forming the rear facet protective film 24A are formed by ECR sputtering as in the first embodiment using an Al metal target material containing 5 atom % of lanthanum (La).

Note that, a plurality of semiconductor laser diodes, each of which includes a first protective film of YAlN and a second protective film of YAlON as a front facet protective film as in the first embodiment, and a first protective film of YAlN and a second protective film of YAlON as a rear facet protective film, and SiO₂/ZrO₂ (in a plurality of cycles) formed on the rear facet protective film, are prepared as a first comparative example.

Furthermore, a plurality of semiconductor laser diodes, each of which includes a first protective film having a thickness of 5 nm and made of AlN and a second protective film made of Al₂O₃ as a front facet protective film, and a first protective film of a single layer having a thickness of 30 nm and made of AlN and a second protective film formed by stacking a plurality of cycles of SiO₂/ZrO₂ as a rear facet protective film are prepared as a second comparative example. In each of the comparative examples, the reflectivity of the front facet protective film is 18%, and the reflectivity of the rear facet is 90%.

The similar reliability testing to that in the first embodiment is performed in the semiconductor laser diode according to the second embodiment prepared as described above. The increasing rate of the operating current in the semiconductor laser diode according to the second embodiment was 6% on average, the COMD did not occur in any of the plurality of laser diodes having the same structures.

Also, in the semiconductor laser diodes according to the first comparative example using YAlN and YAlON instead of LaAlN and LaAlON for forming the front facet protective film 23A, the increasing rate of the operating current was 5% on average. In all of the laser diodes having the same structures, the COMD did not occur. In both cases, an increase in the operating current can be reduced as in the first embodiment. A significant difference because of the differences between materials of LaAlN and YAlN and between LaAlON and YAlON cannot be seen in view of the reliability.

On the other hand, in the semiconductor laser diodes according to the second comparative example, the increasing rate of the operating current was 20% on average. In about 80% of the plurality of laser diodes having the same structures, the COMD has occurred on the rear facets.

The reason why the semiconductor laser diode according to the second embodiment has mitigated an increase in the operating current as compared to the semiconductor laser diodes according to the second comparative example is considered as follows.

Due to high light density, facet deterioration proceeds not only on the front facet of the semiconductor multilayer 25, on which the REDR caused by photoexcited carriers occurs, but also on the rear facet, on which the REDR caused by injected carriers exists. Thus, in the second embodiment, the first protective film 24a provided in the rear facet protective film 24A and made of LaAlN reduces oxidation of the rear facet of the semiconductor multilayer 25, which occurs during the formation of the second protective film 24b and the third protective film 24c, each of which contains oxygen in its composition. Furthermore, the first protective film 24a provided on the rear facet is made of LaAlN, in which AlN contains La, to reduce internal stress, thereby reducing the REDR. Also, oxidation of the first protective film 24a during formation of the second protective film 24b can be reduced by La added to the first protective film 24a.

Moreover, the phenomenon, in which oxygen contained in sealing gas enclosed in a package is diffused into the facet of the semiconductor multilayer 25 through the third protective film 24c, can be reduced by the second protective film 24b.

Since the advantage of adding La can be obtained also by yttrium (Y) similarly to the first embodiment, there is no difference in reliability between LaAlN and YAlN, and between LaAlON and YAlON.

By contrast, in the semiconductor laser diodes according to the second comparative example, each of which includes a protective film of a single layer of AlN and a protective film of multilayer of SiO₂/ZrO₂ as the rear facet of the semiconductor multilayer, the REDR on the rear facet proceeded to cause the COMD since the internal stress in the single layer protective film having a relatively large thickness of 30 nm.

Note that, in the first and second embodiments, in view of advantages in manufacturing, either one of Y and La is added to the first protective films 23a and 23c, and the second protective films 23b and 23d. However, when, e.g., Y is added to the first protective films 23a and 23c, and La is added to the second protective films 23b and 23d, an equivalent advantage of improving the reliability of the present invention can be obtained.

Although the improvement in the reliability is smaller than in the above-described embodiment, Y or La may be added to either one of the first protective films 23a and 23c, and the second protective film 23b and 23d. This is applicable to the first protective film 24a and the second protective film 24b forming the rear facet protective film 24A according to the second embodiment.

Furthermore, by adding silicon (Si) to the protective film according to the present invention, adhesiveness of the film and reliability can be improved at the same time. In the second embodiment, the N composition added to the second protective films 23d and 24b is 30 atom %. Note that the N composition added to the second protective films 23d and 24b preferably ranges from 25 atom % to 40 atom %.

While in the first and second embodiments, nitrogen (N) is added to each of the second protective films 23b, 23d, and 24b, N may not be necessarily added. As described above, in the present invention, the reliability of the semiconductor laser diode made of group III nitride semiconductor can be improved.

While in the first and second embodiments, the front facet protective films 23 and 23A are double layers, the structure is not limited to the double layers but may be triple layers or more. For example, in the case of the triple layers, a third protective film made of Al₂O₃, AlON, AlN, YAlN or the like, can be formed outside the second protective film.

In the first and second embodiments, the outline of the present invention is described using a semiconductor laser diode made of group III nitride semiconductor, the present invention is also useful for improving the reliability of a light-emitting diode made of group III nitride semiconductor. This is because, also in the light-emitting diode, oxidation of the nitride semiconductor on the facet of the element and external diffusion of nitrogen occur during the operation, thereby increasing current leakage on the facet to reduce luminous efficiency. In order to mitigate the reduction in the luminous efficiency, the present invention is useful as described above.

The present invention is useful not only for a semiconductor light-emitting device made of group III nitride semiconductor, but also for a semiconductor light-emitting device made of GaAs or InP. This is because, in such a semiconductor light-emitting device, oxidation of the semiconductor on the facet of the element and external diffusion of the semiconductor constituent atoms during the operation cause deterioration of the facet.

### INDUSTRIAL APPLICABILITY

The semiconductor light-emitting device according to the present invention improves long-time reliability, and is useful for a semiconductor light-emitting device and the like having a protective film (coating film) on a facet of e.g. the cavity.

### DESCRIPTION OF REFERENCE CHARACTERS

11 Substrate
12 N-Type GaN Layer
13 N-Type Cladding Layer
14 N-Type Optical Guide Layer
15 Triple Quantum Well Active Layer
16 P-Type Optical Guide Layer
17 P-Type Electron Blocking Layer
18 P-Type Superlattice Cladding Layer
19 P-Type Contact Layer
20 Mask Film
21 P-Side Electrode
22 N-Side Electrode
23 Front Facet Protective Film
23A Front Facet Protective Film
23a First Protective Film
23b Second Protective Film
23c First Protective Film
23d Second Protective Film
24A Rear Facet Protective Film
24a First Protective Film
24b Second Protective Film
24c Third Protective Film
25 Semiconductor Multilayer

1. A semiconductor light-emitting device, comprising:
a semiconductor multilayer including a facet; and
a first protective film formed on the facet and made of metal nitride, wherein
the metal nitride contains aluminum and nitrogen as main components, and at least one of yttrium and lanthanum.

2. The semiconductor light-emitting device of claim 1, wherein
the metal nitride contains silicon.

3. The semiconductor light-emitting device of claim 1, wherein
the metal nitride is crystalline.

4. The semiconductor light-emitting device of claim 1, further comprising
a second protective film formed on the first protective film, containing aluminum and oxygen as main components, and made of metal oxide containing at least one of yttrium and lanthanum.

5. The semiconductor light-emitting device of claim 4, wherein
the metal oxide contains nitrogen.

6. The semiconductor light-emitting device of claim 4, wherein
the metal oxide is amorphous.

7. The semiconductor light-emitting device of claim 1, wherein
the semiconductor multilayer is made of group III nitride semiconductor.
